(19) United States
(12) Patent Application Publication
(10) Pub. No.: US 2013/0340249 A1
(43) Pub. Date: Dec. 26, 2013

(54) METHOD OF MANUFACTURING MULTILAYER CIRCUIT SUBSTRATE

(71) Applicant: FUJITSU LIMITED, Kawasaki-shi (JP)

(72) Inventor: Takashi KANDA, Kawasaki (JP)

(73) Assignee: FUJITSU LIMITED, Kawasaki-shi (JP)

(21) Appl. No.: 13/870,368

(22) Filed: Apr. 25, 2013

(30) Foreign Application Priority Data
Jun. 21, 2012 (JP) 2012-139677

(51) Int. Cl. H05K 3/46

(52) U.S. Cl. CPC H05K 3/46
USPC 29/852

(57) ABSTRACT

A method of manufacturing a multilayer circuit substrate, the method includes: injecting a conductive paste into through-holes provided in an insulating substrate to one or both sides of which a protection film is attached; cooling and setting the conductive paste injected into the through-holes; and removing the protection film from the insulating substrate after cooling and setting the conductive paste.

### CROSS-REFERENCE TO RELATED APPLICATION

This application is based upon and claims the benefit of priority from the prior Japanese Patent Application No. 2012-139677 filed on Jun. 21, 2012, the entire contents of which are incorporated herein by reference.

### FIELD

The embodiment discussed herein is related to a method of manufacturing a multilayer circuit substrate.

### BACKGROUND

In a known method of connecting certain layers of a multilayer circuit substrate, a conductive paste is used to form interlayer vias. In this case, a method in which a conductive paste is injected into through-holes provided in an insulating substrate, such as a prepreg, to one or both sides of which a protection film is attached, and the insulating substrate is heated and pressed by a hot press machine in the manufacturing process of the multilayer circuit substrate, is widely used. The protection film attached to the insulating substrate is removed after the conductive paste is injected into the through-holes and before the insulating substrate is heated and pressed by the hot press machine.

The followings are reference documents:
[Document 1] Japanese Laid-open Patent Publication No. 2007-335701,
[Document 2] Japanese Laid-open Patent Publication No. 2011-96900,
[Document 3] Japanese Laid-open Patent Publication No. 7-176846,
[Document 4] Japanese Laid-open Patent Publication No. 2010-245193,
[Document 5]Japanese Laid-open Patent Publication No. 2011-108964, and
[Document 6]Japanese Laid-open Patent Publication No. 10-193463.

### SUMMARY

According to an aspect of the invention, a method of manufacturing a multilayer circuit substrate, the method includes: injecting a conductive paste into through-holes provided in an insulating substrate to one or both sides of which a protection film is attached; cooling and setting the conductive paste injected into the through-holes; and removing the protection film from the insulating substrate after cooling and setting the conductive paste.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view of a wiring substrate unit according to an embodiment;

FIG. 2 illustrates a prepreg substrate in a manufacturing process of a multilayer circuit substrate;

FIG. 3 illustrates a state in which protection films are attached to both sides of the prepreg substrate in the manufacturing process of a multilayer circuit substrate;

FIG. 4 illustrates a state in which through-holes are provided in the prepreg substrate to both sides of which the protection films are attached in the manufacturing process of a multilayer circuit substrate;

FIG. 5 illustrates a state in which the conductive paste is injected into the through-holes in the manufacturing process of a multilayer circuit substrate;

FIG. 6 illustrates a state in which the prepreg substrate whose through-holes are filled with the conductive paste is cooled in the manufacturing process of a multilayer circuit substrate;

FIG. 7 illustrates a state in which the protection films are removed from the prepreg substrate in the manufacturing process of a multilayer circuit substrate;

FIG. 8 illustrates a state in which the conductive paste is defrosted in the manufacturing process of a multilayer circuit substrate;

FIG. 9 illustrates a state in which first and second wiring layers are disposed so as to sandwich the prepreg substrate therebetween in the manufacturing process of a multilayer circuit substrate;

FIG. 10 illustrates a state in which hot pressing is performed in the manufacturing process of a multilayer circuit substrate;

FIG. 11 is a graph illustrating the relationship between the paste-filling percentage and the cooling temperature, in which the cooling temperature for cooling the conductive paste in cooling and setting is changed as the parameter; and

FIG. 12 is a graph illustrating the relationship between the paste-filling percentage and the content of metal particle powder in the conductive paste, in which the content of metal particle powder is changed as the parameter.

### DESCRIPTION OF EMBODIMENT

An exemplary embodiment of a method of manufacturing a multilayer circuit substrate will be described in detail below with reference to the drawings.

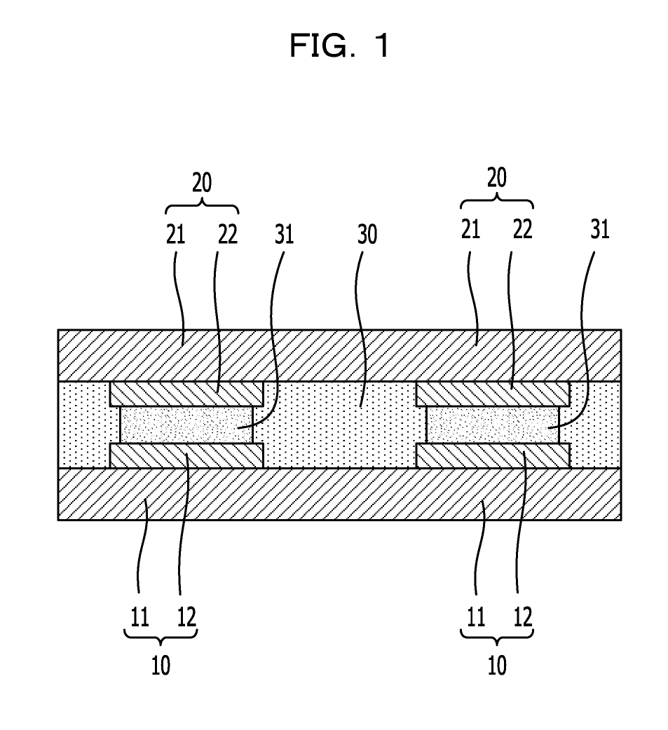

FIG. 1 illustrates the cross-sectional structure of a multilayer circuit substrate 1 according to the embodiment. The multilayer circuit substrate 1 includes a first wiring layer 10, a second wiring layer 20, and an insulating layer 30 that joins them. The first wiring layer 10 includes an insulating resin layer 11 and contact pads 12 formed on the surface of the insulating resin layer 11. The second wiring layer 20 includes an insulating resin layer 21 and contact pads 22 formed on the surface of the insulating resin layer 21.

The insulating resin layers 11 and 21 are resin base members composed of, for example, glass epoxy resin, but are not limited thereto. Furthermore, the contact pads 12 and 22 are formed of a conductive material, such as copper. Note that the surfaces of the contact pads 12 and 22 may be covered by a precious-metal plating film, such as a gold plating film, or a nickel plating film.

The insulating layer 30 is provided with interlayer vias 31 that electrically connect the first wiring layer 10 and the second wiring layer 20. The interlayer vias 31 are formed by injecting a conductive binder into through-holes provided in the insulating layer 30. The binder constituting the interlayer vias 31 is a conductive paste that is heated and cured, as will be described below, and electrically connects the contact pads 12 on the first wiring layer 10 and the contact pads 22 on the second wiring layer 20. Thus, the first wiring layer 10 and the second wiring layer 20 are electrically connected.

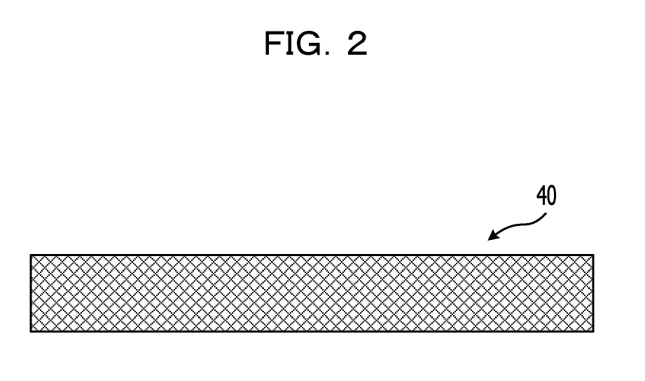

Next, referring to the drawings, a method of manufacturing the multilayer circuit substrate 1 will be described. FIGS. 2 to 10 illustrate the method (process) of manufacturing the multilayer circuit substrate 1. First, as illustrated in FIG. 2, a prepreg substrate 40 is prepared. The prepreg substrate 40 is a semi-cured prepreg formed of a base member composed of, for example, glass fiber cloth impregnated with a heat-curing insulating resin, such as epoxy resin. Note that the base member constituting the prepreg substrate 40 is not limited to the glass fiber cloth, but may be other materials, such as aramid fiber cloth. The other examples of insulating resin used for the prepreg substrate 40 include a thermoplastic resin, such as polyether-ketone (PEEK) resin, besides epoxy resin. The prepreg substrate 40 is an example of an insulating substrate. Although the prepreg substrate 40 is used as an example of the insulating substrate in this embodiment, for example, an insulating resin substrate obtained by etching the copper foil of a copper-plating resin substrate may be used instead.

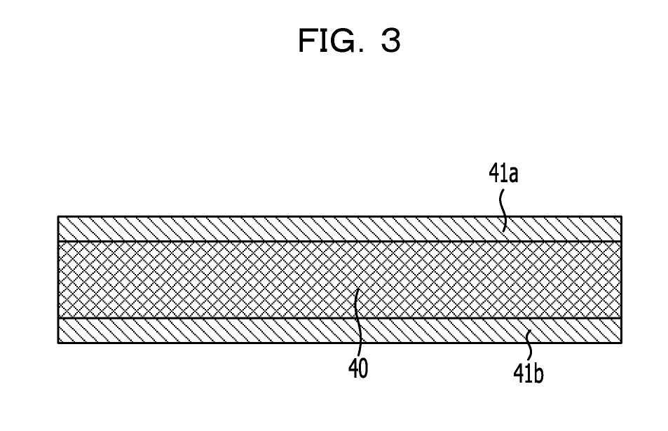

Next, as illustrated in FIG. 3, protection films 41a and 41b that are easy to remove are attached to both sides of the prepreg substrate 40. The protection films 41a and 41b are made of, for example, polyethylene terephthalate resin (PET). The protection films 41a and 41b may be made of various materials, besides PET. Furthermore, when an insulating resin substrate is used instead of the prepreg substrate 40, the protection films 41a and 41b are attached to both sides of the insulating resin substrate.

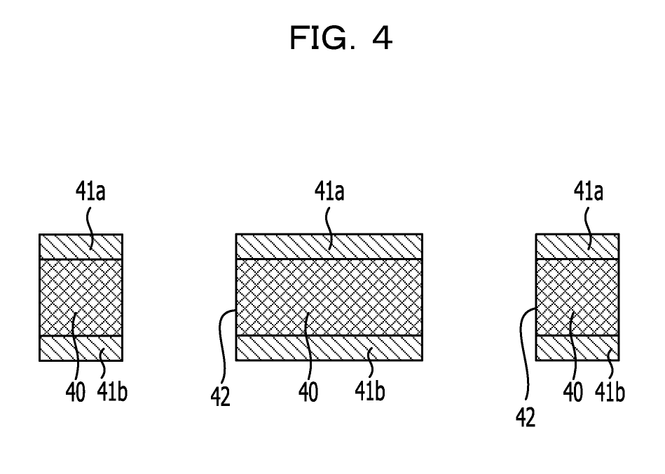

Next, as illustrated in FIG. 4, through-holes 42 are provided in the prepreg substrate 40 after the protection films 41a and 41b are attached to both sides thereof. The through-holes 42 may be provided in the prepreg substrate 40 and the protection films 41a and 41b by laser ablation, drilling, or punching using a punching die. The laser may be carbon dioxide gas laser, UV-YAG laser, or excimer laser.

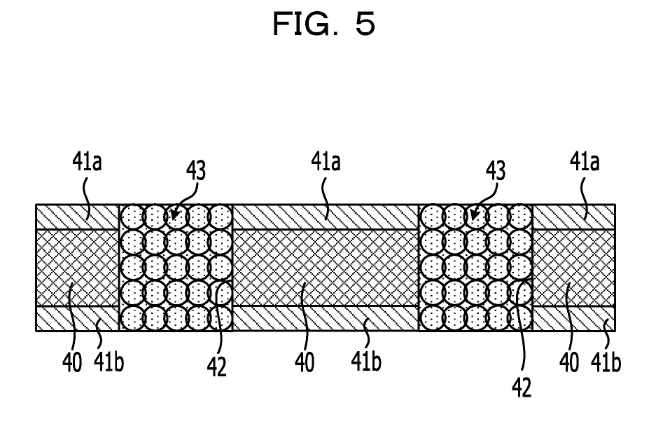

Next, as illustrated in FIG. 5, the conductive paste 43 is squeegeed into the through-holes 42 (injecting). The conductive paste 43 is a mixture of powdered metal particles, such as powdered tin particles or tin bismuth powder, and a resin binder. Each tin particle is supersaturated with copper. The resin binder is composed of a heat-curing resin, such as epoxy resin. The material of the conductive paste 43 is not limited to the above example, but may be a paste formed by mixing fine particles of carbon, silver, or copper with a concentrated viscous thermoplastic resin binder. The conductive paste 43 may contain organic acid that functions as an activator.

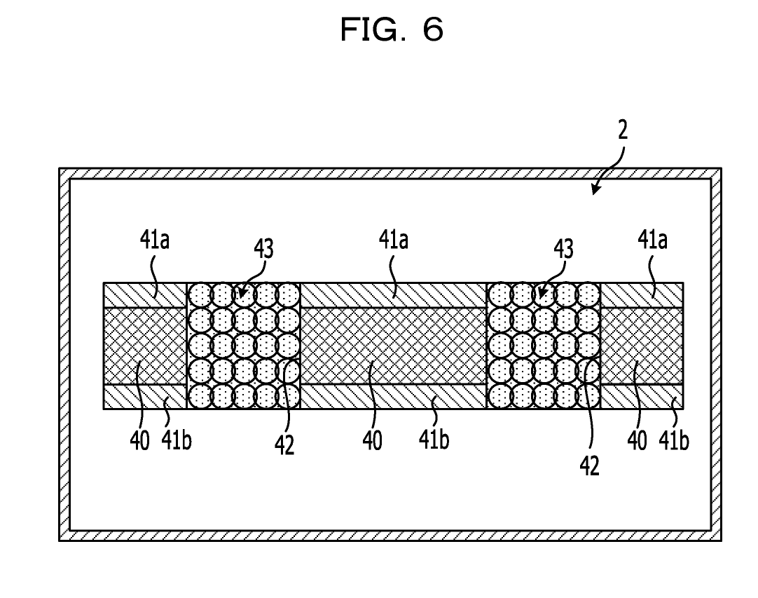

Next, as illustrated in FIG. 6, the prepreg substrate 40 with the through-holes 42 being filled with the conductive paste 43 is disposed in a freezer 2 to cool. As a result, the conductive paste 43 injected into the through-holes 42 is cooled and set (cooling and setting). The cooling temperature of the freezer 2 is set to a temperature below the setting point (for example, −10° C.) of the resin binder contained in the conductive paste 43, and the conductive paste 43 cooled to the cooling temperature is set and frozen. In this embodiment, for example, the temperature of the freezer 2 is set to −20° C., and the cooling duration for which the prepreg substrate 40 is left in the freezer 2 is set to one hour. The cooling temperature and cooling duration may be appropriately changed. Through the cooling and setting, the conductive paste 43 is set.

Although the conductive paste 43 is cooled by leaving the prepreg substrate 40 with the through-holes 42 being filled with the conductive paste 43 in the freezer 2 in this embodiment, the cooling method is not limited thereto, and various methods may be employed. For example, the conductive paste 43 may be locally cooled and set by blowing cold air from a blower nozzle toward the conductive paste 43, not by cooling the whole prepreg substrate 40.

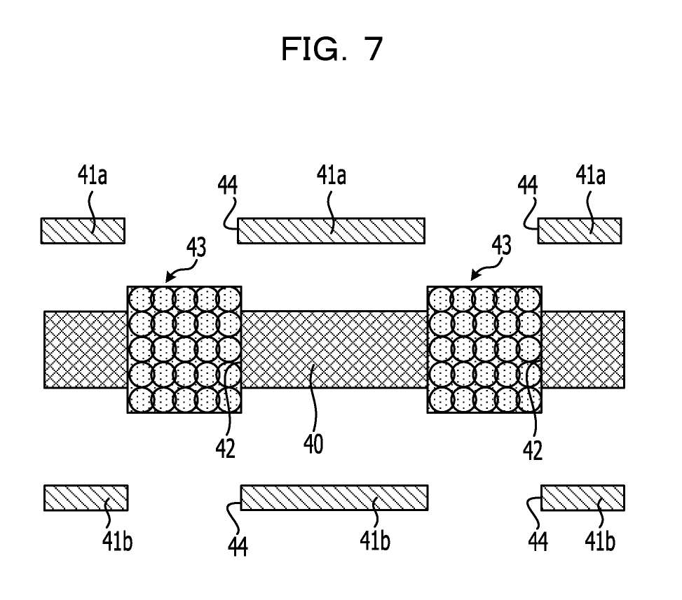

Next, as illustrated in FIG. 7, the protection films 41a and 41b are removed from the prepreg substrate 40 (removal). Herein, through-holes provided in the protection films 41a and 41b are called hole portions 44. Because the conductive paste 43 is frozen, the conductive paste 43 does not adhere to the walls of the hole portions 44 when the protection films 41a and 41b are removed. That is, the protection films 41a and 41b are not removed from the prepreg substrate 40 with the conductive paste 43 adhered to the walls of the hole portions 44. As a result, improper injection of the conductive paste 43 into the through-holes 42 in the prepreg substrate 40, such as chipping or missing of the conductive paste 43, can be suppressed.

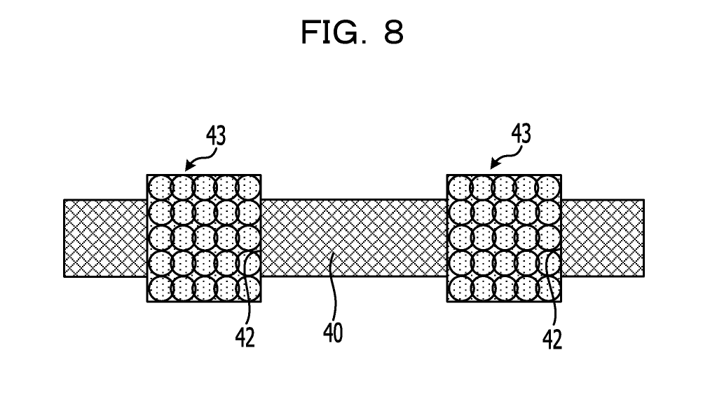

Next, as illustrated in FIG. 8, the prepreg substrate 40 is taken out of the freezer 2 to defrost the conductive paste 43 (defrosting). The conductive paste 43 is defrosted at room temperature. Owing to this, the conductive paste 43 is not preheated, suppressing degradation in quality of the conductive paste 43. The removal may be performed after the prepreg substrate 40 is taken out of the freezer 2.

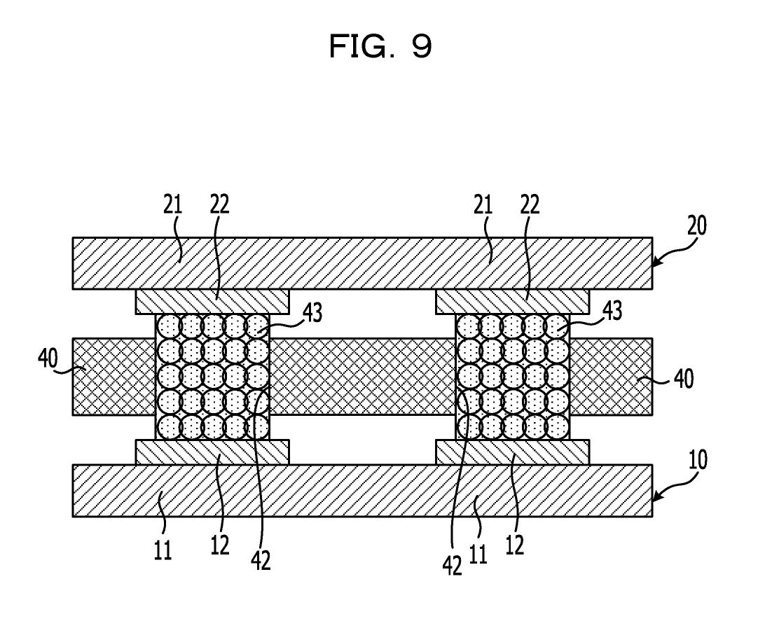

Then, as illustrated in FIG. 9, the first wiring layer 10 and the second wiring layer 20 are disposed so as to sandwich the prepreg substrate 40 therebetween (alignment). More specifically, in a vacuum hot press machine (not illustrated), the first wiring layer 10, the prepreg substrate 40, and the second wiring layer 20 are stacked. The first wiring layer 10 and the second wiring layer 20 may be produced and prepared in a separate process from the insulating layer 30. Alignment marks (not illustrated) used to ease attaching are formed on the surfaces of the insulating resin layer 11 of the first wiring layer 10 and the insulating resin layer 21 of the second wiring layer 20 by laser beam machining or the like. Alignment marks (not illustrated) used to ease attaching are also formed on the surfaces of the prepreg substrate 40 by laser beam machining or the like.

In the alignment, the insulating resin layer 11, the insulating resin layer 21, and the prepreg substrate 40 are aligned using the alignment marks formed thereon as reference. As a result of this alignment, the contact pads 12 on the first wiring layer 10, the contact pads 22 on the second wiring layer 20, and the conductive paste 43 injected into the through-holes 42 in the prepreg substrate 40 are aligned in plan view. The arrangement pattern of the through-holes 42 provided in the prepreg substrate 40 is designed such that the conductive paste 43 and the contact pads 12 and 22 are vertically aligned in plan view, when the prepreg substrate 40 is properly located.

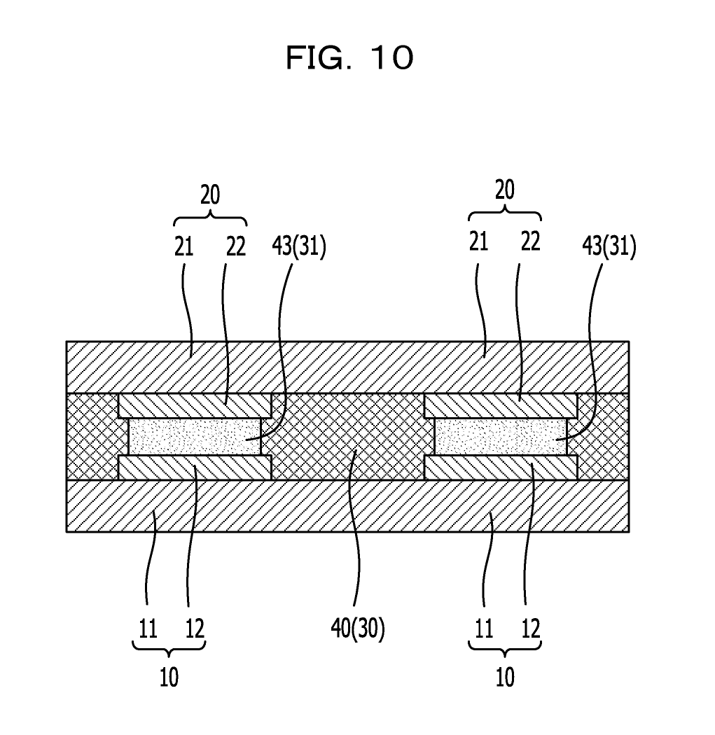

Next, as illustrated in FIG. 10, the prepreg substrate 40 disposed between the first wiring layer 10 and the second wiring layer 20 is heated and pressed in a stacking direction (hot pressing) by the hot press machine. The heating temperature and pressure in the hot pressing may be determined according to the properties of the prepreg substrate 40.

When the hot pressing is started, the insulating resin contained in the prepreg substrate 40 melts and softens. When the softened prepreg substrate 40 is pressed by the hot press machine, the molten insulating resin flows into a surrounding gap space and smooth out the unevenness on the surfaces of the first wiring layer 10 and the second wiring layer 20 due to the presence of the contact pads 12 and 22. Furthermore, in the hot pressing, the resin binder contained in the conductive paste 43 melts, and the metal particles coagulate. After that, the insulating resin in the prepreg substrate 40 and the resin binder in the conductive paste 43 are set. In this way, the insulating layer 30 is formed as illustrated in FIG. 1, the first wiring layer 10 and the second wiring layer 20 are stacked with the insulating layer 30 therebetween, and the multilayer circuit substrate 1 as illustrated in FIG. 1 is formed.

As has been described above, in the method of manufacturing the multilayer circuit substrate 1 according to this embodiment, the cooling and setting to cool and set the conductive paste 43 injected into the through-holes 42 is performed after the injection and before the removal. By removing the protection films 41a and 41b from the prepreg substrate 40 after freezing the conductive paste 43 in this manner, the conductive paste 43 is not detached from the prepreg substrate 40 when the protection films 41a and 41b are removed therefrom. In other words, the conductive paste 43 does not remain on the protection films 41a and 41b. As a result, improper injection of the conductive paste 43 into the through-holes 42 can be suppressed, improving the connection reliability of the interlayer vias 31 in the multilayer circuit substrate 1.

Furthermore, in the method of manufacturing the multilayer circuit substrate 1 according to this embodiment, because the defrosting to defrost the set conductive paste 43 is performed after the removal and before the hot pressing, the following advantages are achieved. Firstly, because the conductive paste 43 is not heated before the hot pressing, the degradation in quality of the conductive paste 43 is suppressed. Secondly, by leaving the conductive paste 43 at room temperature before the hot pressing, an abrupt temperature change of the conductive paste 43 in the hot pressing is suppressed. As a result, bubbles (or voids) are less likely to be formed in the conductive paste 43, and consequently, decrease in connection reliability of the interlayer vias 31 in the multilayer circuit substrate 1 can be suppressed.

### EXAMPLES

An example to study the filling percentage of the prepreg substrate 40 with the conductive paste 43 (hereinbelow, “paste-filling percentage”) when the method of manufacturing the multilayer circuit substrate 1 according to this embodiment is employed will be described below. In the example, the thickness of the prepreg substrate 40 was set to 50 μm, and the thickness of the protection films 41a and 41b was set to 25 μm. The diameter of the through-holes 42 provided in the prepreg substrate 40 was set to 80 μm. The paste-filling percentage is defined as the ratio of the volume of the conductive paste 43 remaining in the through-holes 42 after the protection films 41a and 41b are removed from the prepreg substrate 40 to the capacity of the through-holes 42. The capacity of the through-holes 42 includes the capacity of the hole portions 44 in the protection films 41a and 41b before the protection films 41a and 41b are removed. The paste-filling percentage was measured by examining the appearance of the conductive paste 43 remaining in the through-holes 42 in the prepreg substrate 40 after the injection, the cooling and setting, and the removal, which are described above with reference to FIGS. 5 to 7.

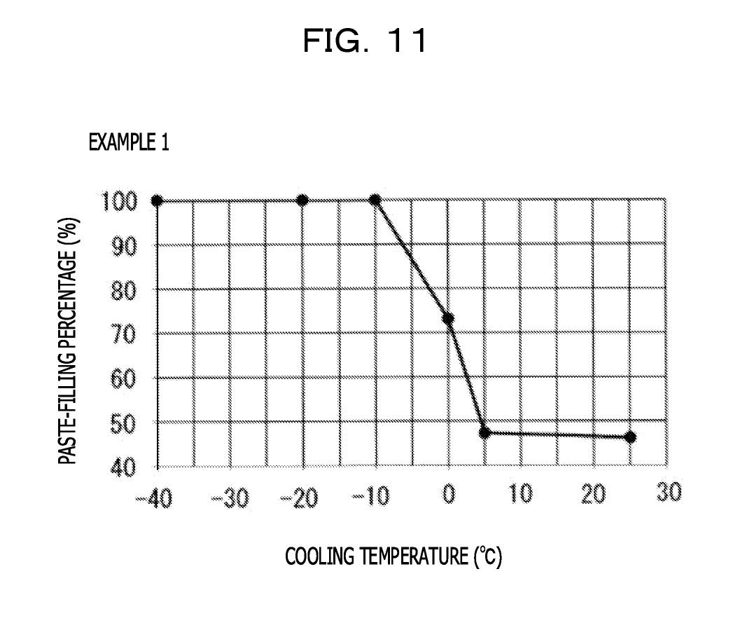

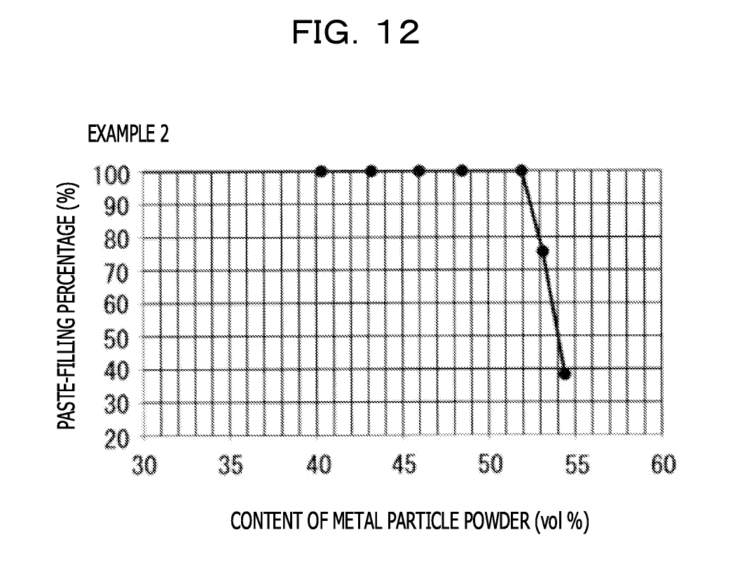

FIG. 11 is a graph illustrating the relationship between the paste-filling percentage and the cooling temperature according to Example 1, in which the cooling temperature for cooling the conductive paste 43 in the cooling and setting is changed as the parameter. FIG. 12 is a graph illustrating the relationship between the paste-filling percentage and the content of metal particle powder according to Example 2, in which the content of metal particle powder in the conductive paste is changed as the parameter. The resin binder contained in the conductive paste 43 used in the examples was an epoxy resin with a setting point of −10° C., and the cooling duration of the conductive paste 43 in the cooling and setting was set to one hour. In Example 1, the content of metal particle powder in the conductive paste 43 was set to 50 vol %. In Example 2, the cooling temperature for cooling the conductive paste 43 in the cooling and setting was set to −20° C.

Example 1 illustrated in FIG. 11 was conducted to study the paste-filling percentage resulting when the cooling temperature for cooling the conductive paste 43 in the cooling and setting is changed as the parameter. In Example 1, the paste-filling percentage reached 100% when the cooling temperature for cooling the conductive paste 43 in the cooling and setting was equal to or lower than the setting point, that is, −10° C., of the resin binder contained in the conductive paste 43. Furthermore, when the cooling temperature for cooling the conductive paste 43 was higher than the setting point of the resin binder (for example, 0° C., 5° C., and 25° C.), the paste-filling percentage decreased as the cooling temperature increased.

The results indicate that, by setting the cooling temperature to a temperature below the setting point of the resin binder, the conductive paste 43 can be appropriately frozen (set), and the conductive paste 43 does not adhere to the protection films 41a and 41b when the protection films 41a and 41b are removed. Accordingly, in the cooling and setting in the method of manufacturing the multilayer circuit substrate 1, it is desirable that the conductive paste 43 be cooled to a target temperature below the setting point of the resin contained in the conductive paste 43.

Furthermore, Example 2 illustrated in FIG. 12 was conducted to study the paste-filling percentage resulting when the content of metal particle powder in the conductive paste 43 is changed as the parameter. In Example 2, the paste-filling percentage reached 100% when the content of metal particle powder was equal to or below 52 vol %. Furthermore, when the content of metal particle powder exceeded 52 vol %, the paste-filling percentage was below 100%, and the paste-filling percentage decreased as the content of metal particle powder increased.

In the frozen (set) conductive paste 43 after the cooling and setting, the strength to keep the external shape (hereinbelow, “freezing strength”) may primarily depend on the content of the resin binder in the conductive paste 43. In Example 2, the larger the content of metal particle powder in the conductive paste 43 is, the smaller the relative content of the resin binder is. Therefore, if the content of metal particle powder in the conductive paste 43 exceeds a certain percentage, the content of the resin binder in the conductive paste 43 falls short, failing to provide sufficient freezing strength, even though the conductive paste 43 is set.

In this example, it is thought that, when the content of metal particle powder exceeded 52 vol %, the sufficient freezing strength to maintain the external shape of the conductive paste 43 in the removal could not be obtained, and a portion thereof adhered to the protection films 41a and 41b. From above, it is desirable that the content of metal particle powder in the conductive paste 43 be equal to or lower than a first reference value (for example, about 50 vol % in this example) that is determined from the standpoint of ensuring the freezing strength of the conductive paste 43 when it is cooled. The appropriate value for this first reference value may vary depending on the type of the resin binder and other conditions. Hence, the first reference value may be determined according to the specifications of the conductive paste 43 and other conditions.

If the content of metal particle powder in the conductive paste 43 is too high, the viscosity of the conductive paste 43 becomes too high, lowering the injection efficiency when injecting the conductive paste 43 into the through-holes 42. Furthermore, when the content of metal particle powder in the conductive paste 43 is too low, the connection reliability of the interlayer vias 31 after producing the multilayer circuit substrate 1 may decrease. Hence, it is desirable that the content of metal particle powder in the conductive paste 43 be equal to or higher than a second reference value that is determined from the standpoint of ensuring the injection efficiency of the conductive paste 43 or the connection reliability of the interlayer vias 31. The appropriate value for the second reference value may vary depending on the type of the resin binder or the other conditions. Thus, the second reference value may be determined according to the specifications of the conductive paste 43 and the other conditions.

The above-described embodiment may be variously modified within a scope not departing from the spirit of this case. For example, although the protection films 41a and 41b are attached to both sides of the prepreg substrate 40 in this embodiment, as illustrated in FIG. 3, a protection film may be attached to one side of the prepreg substrate 40. Also in the case where the protection film is attached to one side of the prepreg substrate 40, by performing the cooling and setting between the injection and the removal, improper injection of the conductive paste 43 into the through-holes 42 can be suppressed. Furthermore, in this embodiment, when the protection film is attached to one side, for example, the top surface, of the prepreg substrate 40, the conductive paste 43 may be injected into the through-holes 42 with the prepreg substrate 40 being disposed on the top surface of the first wiring layer 10. After that, the cooling and setting, the removal, the defrosting, and the hot pressing are performed, and the first wiring layer 10 and the second wiring layer 20 are stacked.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A method of manufacturing a multilayer circuit substrate, the method comprising:
injecting a conductive paste into through-holes provided in an insulating substrate to one or both sides of which a protection film is attached;
cooling and setting the conductive paste injected into the through-holes; and
removing the protection film from the insulating substrate after cooling and setting the conductive paste.

2. The method of manufacturing a multilayer circuit substrate according to claim 1, wherein, when cooling and setting the conductive paste, the conductive paste is cooled to a target temperature below the setting point of resin contained in the conductive paste.

3. The method of manufacturing a multilayer circuit substrate according to claim 1, the method further comprising defrosting the set conductive paste after removing the protection film from the insulating substrate.
